(19) United States
(12) Patent Application Publication
(10) Pub. No.: US 2023/0084826 A1
(43) Pub. Date: Mar. 16, 2023

(54) SUBSTRATE PROCESSING APPARATUS

(71) Applicant: WONIK IPS CO., LTD., Pyeongtaek-si Gyeonggi-do (KR)

(72) Inventors: Tae Dong KIM, Osan-si Gyeonggi-do (KR); Jung Hwan LEE, Osan-si Gyeonggi-do (KR); Cheong Hwan JEONG, Anseong-si Gyeonggi-do (KR); Sung Ho ROH, Yongin-si Gyeonggi-do (KR); Young Jun KIM, Pyeongtaek-si Gyeonggi-do (KR)

(73) Assignee: WONIK IPS CO., LTD., Pyeongtaek-si Gyeonggi-do (KR)

(21) Appl. No.: 17/901,640

(22) Filed: Sep. 1, 2022

(30) Foreign Application Priority Data
Sep. 15, 2021 (KR) 10-2021-0123219

(51) Int. Cl. H01L 21/67; H01L 21/673

(52) U.S. Cl. CPC H01L 21/67017; H01L 21/67393

(57) ABSTRACT

The present invention disclosed herein relates to a substrate processing apparatus, and more particularly, to a substrate processing apparatus that performs substrate processing through a pressure change between a high pressure and a low pressure. The substrate processing apparatus includes: a process chamber (100) comprising a chamber body (110) which has an opened upper portion and in which a through-hole (150) is defined in a bottom surface thereof, and a top lid (140) coupled to the upper portion of the chamber body (110) to define an inner space (S1); a substrate support (200) comprising a substrate support plate (210) which is installed in the process chamber (100) and on which a substrate (1) is seated on a top surface thereof, and a substrate support shaft (220) installed to pass through the through-hole (150) so as to support the substrate support plate (210).

### CROSS-REFERENCE TO RELATED APPLICATIONS

This U.S. non-provisional patent application claims priority under 35 U.S.C. § 119(a) to Korean Patent Application No. 10-2021-0123219, filed on Sep. 15, 2021, in the Korean Intellectual Property Office, the entire contents of which are hereby incorporated by reference.

### FIELD OF THE INVENTION

The present invention disclosed herein relates to a substrate processing apparatus, and more particularly, to a substrate processing apparatus that performs substrate processing through a pressure change between a high pressure and a low pressure.

### BACKGROUND ART

The substrate processing apparatus may perform a process of processing a substrate such as a wafer, in general, perform etching, deposition, heat treatment, and the like on the substrate.

Here, when a film is formed on the substrate through the deposition, a process of removing impurities within the film and improving characteristics of the film after forming the thin film on the substrate is being required.

Particularly, as 3D semiconductor devices and substrates having a high aspect ratio appear, since a deposition temperature is lowered to meet a step coverage standard, or a gas having a high impurity content is inevitably used, the removing of the impurities within the film is becoming more difficult.

Accordingly, there is a need for a substrate processing method, which is capable of improving the characteristics of the thin film by removing the impurities existing in the thin film without deterioration in characteristics of the thin film after forming the thin film on the substrate, and an apparatus for processing the substrate, which performs the method.

In addition, there is a limitation that the deposited thin film is contaminated by a small amount of impurities, which remain in a chamber as well as the thin film on the substrate, and thus, it is necessary to remove the impurities from the inside of the chamber including a substrate support that supports the substrate.

To improve this limitation, Korean Patent Application No. 10-2021-0045294A, which is the related art, disclosures a substrate processing method, in which high-pressure and low-pressure atmospheres are repeatedly formed to reduce imperfection on a surface of a substrate and the inside of a chamber, thereby improving characteristics of a thin film.

However, when the above-described substrate processing method is applied to the substrate processing apparatus according to the related art, since a volume of a processing space for processing a substrate is relatively large to cause a limitation that it is difficult to realize a fast pressure change rate.

That is, the substrate processing apparatus according to the related art has a limitation in that it is difficult to implement a process of repeatedly performing a wide pressure range from a low pressure of about 0.01 Torrs to a high pressure of about 5 Bars within a short time.

Particularly, in the substrate processing apparatus according to the related art, an exhaust space communicating with the processing space is essential to realize a fast pressure change rate, but a volume of the processing space increases according to the exhaust space, and thus, there is a limitation that it is difficult to realize a fast pressure change rate.

### SUMMARY OF THE INVENTION

To solve the above-mentioned limitations, the present invention provides a substrate processing apparatus in which an exhaust space for exhausting a processing space is minimized to realize a fast pressure change rate.

In accordance with an embodiment of the present invention, a substrate processing apparatus of the present invention includes: a process chamber 100 including a chamber body 110 which has an opened upper portion and in which a through-hole 150 is defined in a bottom surface thereof, and a top lid 140 coupled to the upper portion of the chamber body 110 to define an inner space S1; a substrate member 200 including a substrate support plate 210 which is installed in the process chamber 100 and on which a substrate 1 is seated on a top surface thereof, and a substrate support shaft 220 installed to pass through the through-hole 150 so as to support the substrate support plate 210; a gas supply part 400 configured to supply a process gas for the substrate processing; and an exhaust part 500 disposed on a lower portion of the chamber body 110 and configured to exhaust the process gas supplied through the gas supply part 400 to the outside, wherein the chamber body 110 may include an exhaust passage disposed between an outer circumferential surface of the substrate support shaft 220 and an inner surface of the through-hole 150 to communicate with the exhaust part 500.

The process chamber 100 may include an installation groove 130 defined so that the substrate support 200 is installed to be inserted into a bottom surface 120 of the chamber body 110 including the through-hole 150.

The substrate processing apparatus may further include an inner lid part 300 which is installed to be movable vertically in the inner space S1 and of which a portion is in close contact with the bottom surface 120 adjacent to the installation groove 130 through descending to define a sealed processing space S2 in which the substrate support 200 is disposed, wherein the gas supply part 400 may be installed to be adjacent to an edge of the substrate support shaft 220 so as to supply the process gas into the processing space S2.

The substrate processing apparatus may further include an inner lid driving part 600 installed to pass through the top lid 140 so as to drive the vertical movement of the inner lid part 300.

The substrate processing apparatus may further include a filling member 700 installed between the substrate support plate 210 and the installation groove 130 to fill a portion of a spaced space between the substrate support plate 210 and the installation groove, thereby providing an installation groove exhaust passage S3 configured to connect the processing space S2 to the exhaust passage.

The substrate processing apparatus may further include an installation groove exhaust passage S3 defined between the substrate support plate 210 and the installation groove 130 to connect the processing space S2 to the exhaust passage.

The exhaust part 500 may include: an exhaust body 510 installed on at least a portion of an inner surface of the through-hole 150 to support the substrate support shaft 220 and having an opened upper portion to define an exhaust space S4 communicating with the exhaust passage; and at least one or more gas exhaust ports disposed on a side surface of the exhaust body 510 to exhaust the process gas introduced into the exhaust space S4 to the outside.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a substrate processing apparatus according to the present invention;

FIG. 2 is an enlarged cross-sectional view illustrating a portion A of the substrate processing apparatus according to the present invention; and

FIG. 3 is a graph illustrating a pressure change in a processing space through the substrate processing apparatus of FIG. 1.

### DETAILED DESCRIPTION OF THE PREFERRED EMBODIMENTS

Hereinafter, a substrate processing apparatus according to the present invention will be described with reference to the accompanying drawings.

A substrate processing apparatus according to the present invention includes a process chamber 100 including a chamber body 110 which has an opened upper portion and in which a through-hole 150 is defined in a bottom surface thereof, and a top lid 140 coupled to the upper portion of the chamber body 110 to define an inner space S1; a substrate support 200 including a substrate support plate 210 which is installed in the process chamber 100 and on which a substrate 1 is seated on a top surface thereof, and a substrate support shaft 220 installed to pass through the through-hole 150 so as to support the substrate support plate 210; a gas supply part 400 configured to supply a process gas for the substrate processing; and an exhaust part 500 disposed on a lower portion of the chamber body 110 and configured to exhaust the process gas supplied through the gas supply part 400 to the outside. The chamber body 110 may include an exhaust passage disposed between an outer circumferential surface of the substrate support shaft 220 and an inner surface of the through-hole 150 to communicate with the exhaust part 500.

In addition, the substrate processing apparatus according to the present invention may further include an inner lid part 300 which is installed in the inner space S1 and of which a portion is in close contact with the process chamber 100 to define a sealed inner space S2 in which the substrate support 200 is installed.

In addition, the substrate processing apparatus according to the present invention may further include an inner lid driving part 600 installed to pass through a top surface of the process chamber 100 so as to drive the vertical movement of the inner lid part 300.

In addition, the substrate processing apparatus according to the present invention may include a filling member 700 installed between the substrate support 200 and a bottom surface of the process chamber 100.

Here, the substrate 1 to be processed may be understood to include all substrates such as substrates used in display devices such as LCD, LED, and OLED, semiconductor substrates, solar cell substrates, glass substrates, and the like.

The process chamber 100 may have a configuration in which the inner space S1 is defined therein and thus may have various configurations.

For example, the process chamber 100 may include the chamber body 110 having the opened upper portion and the top lid 140 covering the opened upper portion of the chamber body 110 to define the sealed inner space S1 together with the chamber body 110.

In addition, the process chamber 100 may include the bottom surface 120 defining the bottom of the inner space S1 and the installation groove 130 defined in the bottom surface 120 to install the substrate support 200.

In addition, the process chamber 100 may have a through-hole 150 in which the exhaust part 500 to be described later is installed in a bottom surface.

In addition, the process chamber 100 may further include a gate valve for opening and closing a gate provided at one side of the chamber body 110 to load and unload the substrate 1.

The chamber body 110 may have an opened upper portion to define the sealed inner space S1 together with the top lid 140 to be described later.

Here, the chamber body 110 may be made of a metal material including aluminum. As another example, the chamber body 110 may be made of a quartz material and may have a rectangular parallelepiped shape like the chamber that is disclosed in the related art.

The top lid 140 may be coupled to the upper side of the chamber body 110 having the opened upper portion and may be configured to define the sealed inner space S1 together with the chamber body 110.

Here, the top lid 140 may be provided in a rectangular shape on a plane to correspond to the shape of the chamber body 110 and may be made of the same material as the chamber body 110.

In addition, the top lid 140 may have a plurality of through-holes so that the inner lid driving part 600 to be described later is installed to pass therethrough, and an end of a bellows 630 to be described later may be coupled to the top lid 140 to prevent various gases and foreign substances from leaking.

The configuration of the top lid 140 may be omitted, and the chamber body 110 may be integrally provided to define the sealed inner space S1 therein.

The process chamber 100 may include the bottom surface 120, of which an inner bottom surface defines the bottom of the inner space S1, and the installation groove 130 defined to install the substrate support 200.

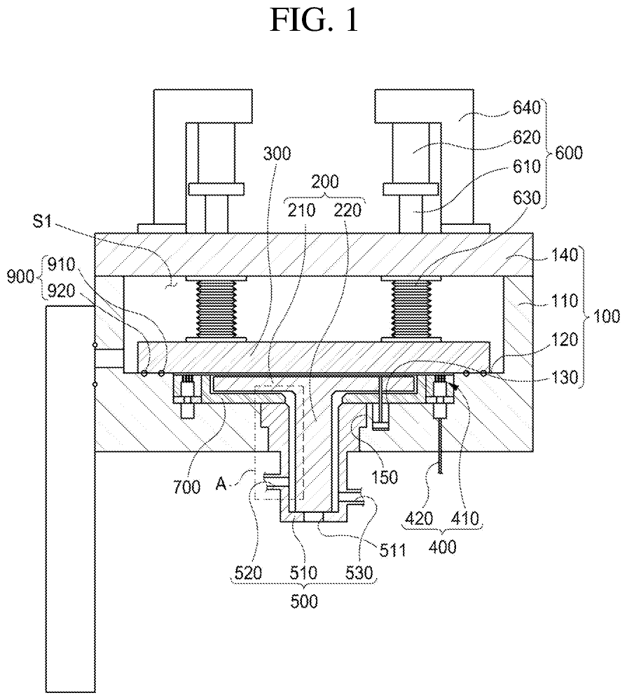

More specifically, as illustrated in FIG. 1, in the process chamber 100, the installation groove 130 may be defined with a height difference at a central side of the bottom surface to correspond to the substrate support 200 to be described later, and the bottom surface 120 may be defined on an edge of the installation groove 130.

That is, in the process chamber 100, the installation groove 130 for installing the substrate support 200 may be defined with the height difference in the inner bottom surface, and the other portion may be defined as the bottom surface 120 at a height higher than the installation groove 130.

The gate valve may have a configuration for opening and closing the gate disposed at one side of the chamber body 110 to load and unload the substrate 1 and may have various configurations.

Here, the gate valve may be in close contact with or released from the chamber body 110 through vertical driving and forward/backward driving to open or close the gate. For another example, the gate valve may open or close the gate through single driving in a diagonal direction. In this process, various types of driving methods disclosed in the related art, such as a cylinder, a can, an electromagnetism, and the like may be applied.

The through-hole 150 may have a configuration defined in the bottom surface of the process chamber 100, and more specifically, is defined in the bottom surface of the process chamber 100 to communicate with the processing space S2 to be described later, and thus, the exhaust part 500 for exhausting the processing space S2 may be installed.

That is, the through-hole 150 may be defined in the bottom surface of the process chamber 100 to communicate with the processing space S2 defined through descending of the inner lid part 300 to be described later, and the exhaust part 500 may be installed.

The through-hole 150 may be installed to pass through the substrate support shaft 220 of the substrate support part 200 to be described later, and thus, the process gas within the processing space S2 may be exhausted through an exhaust passage provided between the substrate support shaft 220 and an inner surface of the through-hole 150.

The substrate support 200 may have a configuration that is installed in the process chamber 100 so that the substrate 1 is seated on a top surface thereof and may have various configurations.

That is, the substrate support 200 may support the substrate 1 to be processed by seating the substrate 1 on the top surface thereof and may be fixed during the substrate processing process.

In addition, the substrate support 200 may include a heater therein to provide a temperature atmosphere in the processing space S2 for the substrate processing.

For example, the substrate support 200 may include a substrate support plate 210 having a planar circular shape on which the substrate 1 is seated on a top surface thereof, and a substrate support shaft 220 passing through the bottom surface of the process chamber 100 so as to be connected to the substrate support plate 210.

In addition, the substrate support 200 may include a heater installed in the substrate support plate 210 to heat the substrate 1 seated on the substrate support plate 210.

The substrate support plate 210 may have a configuration in which the substrate 1 is seated on the top surface thereof and may be provided as a plate having a planar circular shape corresponding to the shape of the substrate 1.

Here, the substrate support plate 210 may be provided with a heater therein to create a process temperature for the substrate processing in the processing space S2. Here, the process temperature may be about 400° C. to 550° C.

The substrate support shaft 220 may have a configuration that passes through the through-hole 150 of the process chamber 100 so as to be connected to the substrate support plate 210 and may have various configurations.

The substrate support shaft 220 may pass through the bottom surface of the process chamber 100 so as to be coupled to the substrate support plate 210, and various conductors for supplying power to the heater may be installed in the substrate support shaft 220.

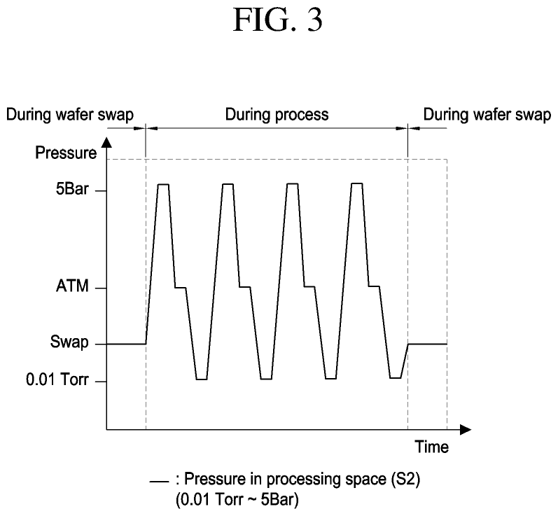

As illustrated in FIG. 3, the substrate processing apparatus according to the present invention may be an apparatus for performing the substrate processing in which a high-pressure and low-pressure atmosphere is repeatedly changed and created within a short time, and more particularly, it is necessary to repeatedly change a pressure range of about 0.01 Torrs at a pressure change rate of about 1 Bar/s.

However, when considering a vast space volume of the inner space S1 of the chamber body 110, the above-described pressure change rate may not be achieved, and thus, there is a need to minimize the volume of the processing space S2 for the substrate processing.

For this, the substrate processing apparatus according to the present invention includes an inner lid part 300 which is installed to be vertically movable in the inner space S1 and of which a portion is in close contact with the process chamber 100 through descending to define the sealed processing space S2, in which the substrate support 200 is disposed.

The inner lid part 300 may have a configuration which is installed to be vertically movable in the inner space S1 and of which a portion is in close contact with the process chamber 100 through the descending to define the sealed processing space S2, in which the substrate support 200 is disposed.

That is, the inner lid part 300 may be installed to be vertically movable at an upper side of the substrate support 200 in the inner space S1 so as to be in close contact with at least a portion of the inner surface of the process chamber 110 through the descending, and thus, the sealed processing space S may be defined between the inner lid part 300 and the inner bottom surface of the process chamber 100 as necessary.

Thus, the substrate support 200 may be disposed in the processing space S2 to perform the substrate processing on the substrate 1 seated on the substrate support 200 in the processing space S2 having the minimized volume.

For example, an edge of the inner lid part 300 may be in close contact with the bottom surface 120 through the descending to define the sealed processing space S2 between the bottom surface and the inner bottom surface of the process chamber 100.

For another example, the edge of the inner lid part 300 may be in close contact with the inner surface of the process chamber 100 through the descending to define the sealed processing space S2.

The edge of the inner lid part 300 may be in close contact with the bottom surface 120 through the descending to define the sealed processing space S2, and the substrate support 200 installed in the installation groove 130 may be disposed within the processing space S2.

That is, as illustrated in FIG. 1, the edge of the inner lid part 300 may be in close contact with the bottom surface 120 disposed at a high position with a height difference with respect to the installation groove through the descending to define the sealed processing space S2 between the bottom surface and the installation groove 130.

Here, the substrate support 200, more specifically, the substrate support plate 210 and the filling member 700 may be installed in the installation groove 130 to minimize the volume of the processing space S2 and dispose the substrate 1 to be processed on the top surface thereof.

In this process, to minimize the volume of the processing space S2, the installation groove 130 may have a shape corresponding to the substrate support 200 installed in the processing space S2, more particularly, may be provided as a groove having a cylindrical shape corresponding to the circular substrate support plate 210.

That is, the installation groove 130 may have a shape corresponding to that of the substrate support plate 210 so that a remaining space except for the space, in which the substrate support plate 210 and the filling member 700 are installed, in the installation space, in which the installation groove 130 is defined, is minimized.

In this process, to prevent an interference between the substrate 1 seated on the top surface of the substrate support plate 210 and the inner lid part 300 from occurring, the bottom surface 120 may be disposed at a height higher than that of the top surface of the substrate 1 seated on the substrate support 200.

It means that, as a distance between the substrate 1 seated on the substrate support 200 and the bottom surface of the inner lid part 300 increases, the processing space S2 increases also in volume. Thus, the height of the bottom surface 120 may be set at a position at which the distance is minimized while preventing the interference between the substrate 1 and the inner lid part 300 from occurring.

The inner lid part 300 may have a configuration that moves vertically through the inner lid driving part 600 and may have various configurations.

The inner lid part 300 may have a configuration that is vertically movable in the inner space through the inner lid driving part 600.

Here, the inner lid part 300 may cover the installation groove 130 on a plane, and the edge of the inner lid part 300 may have a size corresponding to a portion of the bottom surface 120. In addition, the edge may be in close contact with the bottom surface 120 to define the sealed processing space S2 between the installation groove 130 and the inner lid part 300.

For another example, the edge of the inner lid part 300 may be in close contact with the inner surface of the process chamber 100 to define the processing space S2.

In addition, to effectively achieve and maintain the process temperature in the sealed processing space S2 defined according to the vertical movement, the inner lid part 300 may be made of a material having an excellent thermal insulation effect that is capable of preventing the temperature of the processing space S2 from being lost to the inner space.

The sealing part 900 may have a configuration provided on at least one of the inner lid part 300 or the bottom surface 120 of the process chamber 100 and may be provided to correspond to a position at which the bottom surface 120 of the processing chamber 100 and the inner lid part 300 are in close contact with each other.

That is, when the edge of the inner lid part 300 is in close contact with the bottom surface 120 to define the sealed processing space S2, the sealing part 900 may be provided along an edge of the bottom surface of the inner lid part 300 so as to be in contact with the bottom surface 120.

Thus, the sealing part 900 may induce the formation of the sealed processing space S2 and prevent a process gas of the processing space S2 from leaking to the outside of the inner space.

For example, the sealing part 900 may include a first sealing member 910 provided along the edge of the bottom surface of the inner lid part 300 and a second sealing member 920 provided at a position spaced a predetermined distance from the first sealing member 910.

Here, each of the first sealing member 910 and the second sealing member 920 may be an O-ring according to the related art, and the first sealing member 910 and the second sealing member 920 may be installed to be spaced a predetermined distance from each other along the edge of the bottom surface of the inner lid part 300.

That is, the first sealing member 910 and the second sealing member 920 may perform double sealing on the processing space S2 to prevent the process gas from leaking from the processing space S2 to the outside.

The sealing part 900 may be installed by being inserted into an insertion groove provided in the bottom surface 120 and may be in close contact with or separated from the inner lid part 300 according to the vertical movement of the inner lid part 300.

For another example, the sealing part 900 may also be provided on the bottom surface of the inner lid part 300.

The gas supply part 400 may communicate with the processing space S2 to supply the process gas to the processing space S2 and may have various configurations.

For example, the gas supply part 400 may include a gas supply nozzle 410 exposed to the processing space S2 to supply the process gas into the processing space S2 and a gas supply passage 420 passing through the process chamber 100 so as to be connected to the gas supply nozzle 410 and transfer the process gas supplied through the gas supply nozzle 410.

Here, as illustrated in FIG. 1, the gas supply part 400 may be installed to be adjacent to the substrate support 200 on the edge of the installation groove 130 to supply the process gas to the processing space S2.

The processing space S2 may be defined between a portion of the bottom surface of the inner lid part 300 and the top surfaces of the gas supply part 400 and the substrate support 200.

The gas supply nozzle 410 may have a configuration that is exposed to the processing space S2 to supply the process gas into the processing space S2 and may have various configurations.

For example, the gas supply nozzle 410 may be installed to be adjacent to a side surface of the substrate support plate 210 on the edge of the installation groove 130 and may inject the process gas upward or toward the substrate support plate 210 to supply the process gas into the processing space S2.

Here, the gas supply nozzle 410 may be provided to surround the substrate support plate 210 on the edge of the installation groove 130 and may inject the process gas from at least a portion of the side surface of the substrate support plate 210 on the plane.

For example, the gas supply nozzle 410 may inject the process gas from the edge of the installation groove 130 toward the bottom surface of an inner lid 310 and may supply the process gas to generate a desired pressure within a short time in the processing space S2 according to the minimized volume of the processing space S2.

The gas supply passage 420 may pass through the bottom surface of the process chamber 100 so as to be connected to an external process gas storage part and may receive the process gas to supply the process gas to the process gas supply nozzle 410.

Here, the gas supply passage 420 may be a pipe installed to pass through the bottom surface of the process chamber 100. For another example, the gas supply passage 420 may be provided by processing the bottom surface of the process chamber 100.

The inner lid driving part 600 may be installed to pass through the top surface of the process chamber 100 so as to drive the vertical movement of the inner lid part 300 and may have various configurations.

For example, the inner lid driving part 600 may include a plurality of driving rods 610, each of which one end passes through the top surface of the process chamber 100 and is coupled to the inner lid part 300, and at least one driving source 620 connected to the other end of each of the plurality of driving rods 610 to drive the driving rods 610 vertically.

In addition, the inner lid driving part 600 may further include a fixing support 630 installed on the top surface of the process chamber 100, i.e., the top lid 140 to fix and support the end of the driving rod 610 and a bellows 630 installed to surround the driving rod 610 between the top surface of the process chamber 100 and the inner lid part 300.

The driving rod 610 may have a configuration having one end passing through the top surface of the process chamber 100 so as to be coupled to the inner lid part 300 and the other end coupled to the driving source 620 outside the process chamber 100 to drive the inner lid part 300 vertically through the vertical movement due to the driving source 620.

Here, the driving rod 610 may be provided in plurality, more particularly, two or four to be coupled to the top surface of the inner lid part 300 at a predetermined interval so that the inner lid part 300 moves vertically while being maintained horizontally.

The driving source 620 may have a configuration that vertically drives the driving rod 610 installed and coupled to the fixing support 640 and may have various configurations.

The driving source 620 may be applied to any configuration as long as it is driving method that is disclosed in the related art, for example, various driving methods such as a cylinder method, an electromagnetic driving, screw motor driving, cam driving, and the like may be applied.

The bellows 630 may have a configuration that is installed to surround the driving rod 610 between the top surface of the process chamber 100 and the inner lid part 300 to prevent the gas in the inner space S1 from leaking thought the top surface of the process chamber 100.

Here, the bellows 630 may be installed in consideration of the vertical movement of the inner lid part 300.

The exhaust part 500 may have a configuration that is installed to surround the substrate support shaft 220 in the through-hole 150 and exhausts the process gas to the outside, and may have various configurations.

For example, as shown in FIG. 1, the exhaust part 500 is installed on at least a portion of the inner surface of the through-hole 150 to support the substrate support shaft 220 and communicate with the exhaust passage. An exhaust body 510 having an open top to form an exhaust space S4, and at least one or more gases formed on the side of the exhaust body 510 to exhaust the process gas flowing into the exhaust space S4 to the outside It may include an exhaust port.

That is, the exhaust part 500 may be installed in the through-hole 150 of the process chamber 100 to provide an exhaust space S4 communicating with the processing space S2 therein.

Here, the exhaust body 510 may be installed to surround the substrate support shaft 220 in the through-hole 150 of the process chamber 100 and may communicate with the processing space S2, which is defined according to the descending of the inner lid part 300, through an installation groove exhaust passage S3.

In addition, the exhaust body 510 may have a lower through-hole 511 so that various conductors connected to a heater installed in the substrate support plate through the above-described substrate support shaft 220 are installed to pass therethrough.

The exhaust body 510 may have gas exhaust ports different from each other depending on a pressure state of the processing space S2. That is, the exhaust body 510 may include a high-pressure exhaust port 520 connected to an external exhaust device to exhaust a high-pressure process gas when performing the exhaust for a high-pressure gas higher than the normal pressure of the processing space S2 and a low-pressure exhaust port 530 connected to an external vacuum pump to exhaust a low-pressure process gas when performing the exhaust for a low-pressure gas lower than the normal pressure of the pressing space S2.

As described above, when the substrate support 200 is installed in the installation groove 130, a space may be defined between the substrate support 200, more particularly, the substrate support plate 210 and the installation groove 130 to increase in volume of the installation groove exhaust passage S3, thereby acting as a factor that increases in volume of the processing space S2.

To solve this limitation, when the substrate support 200 is simply installed to be in contact with the installation groove 130, heat supplied through the heater existing in the substrate support 200 may be lost to the process chamber 100 through the bottom surface of the process chamber 100, i.e., the installation groove 130 to cause a heat loss. As a result, it may be difficult to set and maintain the process temperature with respect to the processing space S2, and efficiency may be deteriorated.

To solve this limitation, the filling member 700 according to the present invention may have a configuration that is installed between the substrate support 200 and the bottom surface of the process chamber 100, and may have various configurations.

For example, the filling member 700 may be installed in the installation groove 130, and in the state of being installed in the insulation groove 130, the substrate support plate 210 may be installed at the upper side to minimize a remaining volume between the installation groove 130 and the substrate support plate 210, thereby reducing the volumes of the installation groove exhaust passage S3 and the processing space S2.

For this, the filling member 700 may be provided in a shape corresponding to the interspace between the installation groove 130 and the substrate support 200 so that the processing space S2 is minimized.

More specifically, the filling member 700 may have a planar circular shape and may be provided in shape corresponding to the interspace between the installation groove 130, which is defined to have a predetermined depth from the bottom surface 120 with the height difference, and the substrate support plate 210.

The filling member 700 may be made of at least one of quartz, ceramic, or SUS.

In addition, the filling member 700 may not only simply occupy the space between the installation groove 130 and the substrate support 200 to minimize the volume of the processing space S2, but also minimize the loss of the heat transferred to the substrate 1 through the substrate support 200 through thermal insulation and furthermore reflect the heat that is lost to the processing space S2 through thermal reflection.

To provide the installation groove exhaust passage S3 between the side surface and the bottom surface of the substrate support 200, the filling member 700 may be installed to be adjacent to at least one of the side surface or the bottom surface of the substrate support plate 210 and may be spaced apart from the substrate support plate 210 to surround the bottom surface and the side surface of the substrate support plate 210.

Hereinafter, the installation groove exhaust passage S3 for exhausting the process gas according to the present invention will be described in detail with reference to the accompanying drawings.

The installation groove exhaust passage S3 may be provided to communicate with the exhaust part 500 between the substrate support 200 and the inner bottom surface of the process chamber 100.

That is, the installation groove exhaust passage S3 may be provided between the side and bottom surfaces of the above-described substrate support plate 210 of the substrate support 200 and the inner bottom surface of the process chamber 100. Here, the formed installation groove exhaust passage S3 may communicate with the through-hole 150 of the process chamber 100, in which the exhaust part 500 is installed, to transfer the process gas to the exhaust space S4 of the exhaust part 500.

More specifically, the installation groove exhaust passage S3 may be provided along the side and bottom surfaces of the substrate support plate 210, which is installed in the installation groove 130, and an inner wall of the installation groove 130.

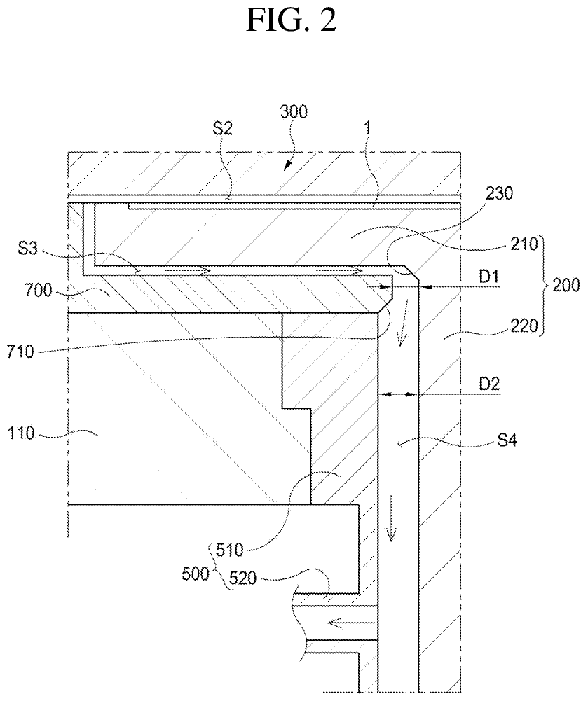

In addition, for another example, as illustrated in FIG. 2, the filling member 700 may be installed in the installation groove 130 and be disposed between the side and bottom surfaces of the substrate support plate 210 and an opposite surface of the filling member 700.

Here, a volume of the installation groove exhaust passage S3 may be provided to a preset level to perform smooth exhaust while minimizing the volume of the processing space S2. For this, a distance between the filling member 700 and the substrate support plate 210 may be adjusted.

As illustrated in FIG, 2, in the installation groove exhaust passage S3, an end of the filling member 700 may be connected to the exhaust space S4 at a coupling position between the substrate support shaft 220 and the substrate support plate 210, and a moving direction may be changed from horizontal movement to vertical movement.

Here, to maintain an exhaust flow of the exhausted process gas and prevent backflow, a guide surface 230 that induces the flow of the exhaust gas may be disposed at the coupling position between the substrate support shaft 220 and the substrate support plate 210. In this case, the guide surface 230 may be provided at a corresponding angle to convert the horizontal direction into the vertical downward direction in the flow of the exhaust gas.

In addition, a boundary 710 of the end of the filling member 700, which is opposite to the guide surface 230, may also be provided to have an inclination that is inclined from the horizontal direction to the vertical direction.

To induce the smooth downward movement of the exhaust gas passing through the installation groove exhaust passage S3 in the exhaust part 500, various embodiments may be applied.

As an example, as illustrated in FIG. 2, a first horizontal distance D1 between a substrate support shaft 220-side end of the filling member 700 and the substrate support shaft 220 may be less than a second horizontal distance D2 between an inner surface of the exhaust part 500 and the substrate support shaft 220 to induce the smooth flow of the exhaust gas from the end of the filling member 700 to the exhaust space S4.

In the substrate processing apparatus according to the present invention, the processing space may communicate with the exhaust space, and thus, the volume of the processing space and the volume of the exhaust space communicating with the processing space may act as the factors that determine the time required for adjusting the pressure in the processing space. Therefore, there may be the advantage in that the volume of the exhaust space is minimized to reduce the overall volume, thereby improving the pressure change rate for the wide pressure range.

In addition, the exhaust part communicating with the processing space to exhaust the processing space may not be separately provided, and the space in which the substrate support shaft is disposed may be utilized as the exhaust part. Therefore, there may be the advantage in that there is no separate exhaust space, and thus, the exhaust space is reduced.

As a result, the substrate processing apparatus according to the present invention may have the advantage of reducing the overall volume of the processing space by minimizing the exhaust space for adjusting the pressure of the processing space by communicating with the processing space to realize the fast pressure change rate.

Although the above description merely corresponds to some exemplary embodiments that may be implemented by the present invention, as well known, the scope of the present invention should not be interpreted as being limited to the above-described embodiments, and all technical spirits having the same basis as that of the above-described technical spirit of the present invention are included in the scope of the present invention.

What is claimed is:

1. A substrate processing apparatus comprising:
a process chamber comprising a chamber body which has an opened upper portion and in which a through-hole is defined in a bottom surface thereof, and a top lid coupled to the upper portion of the chamber body to define an inner space;
a substrate support comprising a substrate support plate which is installed in the process chamber and on which a substrate is seated on a top surface thereof, and a substrate support shaft installed to pass through the through-hole so as to support the substrate support plate;
a gas supply part configured to supply a process gas for the substrate processing; and
an exhaust part disposed on a lower portion of the chamber body and configured to exhaust the process gas supplied through the gas supply part to the outside,
wherein the chamber body comprises an exhaust passage disposed between an outer circumferential surface of the substrate support shaft and an inner surface of the through-hole to communicate with the exhaust part.

2. The substrate processing apparatus of claim 1, wherein the process chamber comprises an installation groove defined so that the substrate support is installed to be inserted into a bottom surface of the chamber body comprising the through-hole.

3. The substrate processing apparatus of claim 2, further comprising an inner lid part which is installed to be movable vertically in the inner space and of which a portion is in close contact with the bottom surface adjacent to the installation groove through descending to define a sealed processing space in which the substrate support is disposed,
wherein the gas supply part is installed to be adjacent to an edge of the substrate support shaft so as to supply the process gas into the processing space.

4. The substrate processing apparatus of claim 3, further comprising an inner lid driving part installed to pass through the top lid so as to drive the vertical movement of the inner lid part.

5. The substrate processing apparatus of claim 3, further comprising a filling member installed between the substrate support plate and the installation groove to fill a portion of a spaced space between the substrate support plate and the installation groove, thereby providing an installation groove exhaust passage configured to connect the processing space to the exhaust passage.

6. The substrate processing apparatus of claim 3, further comprising an installation groove exhaust passage defined between the substrate support plate and the installation groove to connect the processing space to the exhaust passage.

7. The substrate processing apparatus of any one of claims 1, wherein the exhaust part comprises:
an exhaust body installed on at least a portion of an inner surface of the through-hole to support the substrate support shaft and having an opened upper portion to define an exhaust space communicating with the exhaust passage; and
at least one or more gas exhaust ports disposed on a side surface of the exhaust body to exhaust the process gas introduced into the exhaust space to the outside.
